(19) United States
(12) Patent Application Publication
(10) Pub. No.: US 2024/0349577 A1
(43) Pub. Date: Oct. 17, 2024

(54) DISPLAY DEVICE, MOTHER SUBSTRATE FOR DISPLAY DEVICE AND MANUFACTURING METHOD OF DISPLAY DEVICE

(71) Applicant: Japan Display Inc., Tokyo (JP)

(72) Inventors: Ryota TAKASAKI, Tokyo (JP); Naoya IWAHASHI, Tokyo (JP); Sho YANAGISAWA, Tokyo (JP)

(73) Assignee: Japan Display Inc., Tokyo (JP)

(21) Appl. No.: 18/605,835

(22) Filed: Mar. 15, 2024

(30) Foreign Application Priority Data
Apr. 11, 2023 (JP) 2023-064254

(51) Int. Cl. H10K 59/80; H10K 59/12; H10K 59/122

(52) U.S. Cl. CPC H10K 59/873; H10K 59/1201; H10K 59/122

(57) ABSTRACT

According to one embodiment, a display device includes a substrate, an organic insulating layer provided over a display area which displays an image and a surrounding area located on an external side relative to the display area above the substrate, a lower electrode provided on the organic insulating layer in the display area, an organic layer provided on the lower electrode and including a light emitting layer, and an upper electrode provided on the organic layer. In the surrounding area, the organic insulating layer includes a removed portion and has a stepwise cross section in which a thickness decreases toward the removed portion.

### CROSS-REFERENCE TO RELATED APPLICATION

This application is based upon and claims the benefit of priority from Japanese Patent Application No. 2023-064254, filed Apr. 11, 2023, the entire contents of which are incorporated herein by reference.

### FIELD

Embodiments described herein relate generally to a display device, a mother substrate for a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a plan view showing an example of a mother substrate 100.

FIG. 5 is a cross-sectional view showing a configuration example of the mother substrate 100 including a pad PD.

FIG. 6 is a cross-sectional view showing another configuration example of the mother substrate 100 including a pad PD.

FIG. 7 is a cross-sectional view showing another configuration example of the mother substrate 100 including a pad PD.

FIG. 8 is a cross-sectional view showing a configuration example of the mother substrate 100 including a cut line CL.

FIG. 9 is a cross-sectional view showing another configuration example of the mother substrate 100 including a cut line CL.

FIG. 10 is a cross-sectional view showing another configuration example of the mother substrate 100 including a cut line CL.

FIG. 11 is a cross-sectional view showing another configuration example of the mother substrate 100 including a cut line CL.

FIG. 12 is a cross-sectional view showing another configuration example of the mother substrate 100 including a cut line CL.

FIG. 13 is a cross-sectional view showing another configuration example of the mother substrate 100 including a cut line CL.

FIG. 14 is a cross-sectional view showing another configuration example of the mother substrate 100 including a cut line CL.

FIG. 15 is a cross-sectional view showing another configuration example of the mother substrate 100 including a cut line CL.

FIG. 16 is a cross-sectional view showing another configuration example of the mother substrate 100 including a cut line CL.

FIG. 17 is a diagram for explaining the manufacturing method of the display device DSP.

FIG. 18 is a diagram for explaining the manufacturing method of the display device DSP.

FIG. 19 is a diagram for explaining the manufacturing method of the display device DSP.

FIG. 20 is a diagram for explaining the manufacturing method of the display device DSP.

FIG. 21 is a diagram for explaining the manufacturing method of the display device DSP.

FIG. 22 is a diagram for explaining the manufacturing method of the display device DSP.

FIG. 23 is a cross-sectional view for explaining the state in which a multilayer film 115 is formed in the pad PD shown in FIG. 5.

FIG. 24 is a cross-sectional view for explaining the state in which a multilayer film 115 is formed in a pad PD according to a comparative example.

### DETAILED DESCRIPTION

Embodiments described herein aim to provide a display device, a mother substrate for a display device and a manufacturing method of a display device such that the reduction in reliability can be prevented.

In general, according to one embodiment, a display device comprises a substrate, an organic insulating layer provided over a display area which displays an image and a surrounding area located on an external side relative to the display area above the substrate, a lower electrode provided on the organic insulating layer in the display area, an organic layer provided on the lower electrode and including a light emitting layer, and an upper electrode provided on the organic layer. In the surrounding area, the organic insulating layer comprises a removed portion and comprises a stepwise cross section in which a thickness decreases toward the removed portion.

According to another embodiment, a mother substrate for a display device comprises a plurality of panel portions, a margin portion on an external side relative to the panel portions, an organic insulating layer provided over the panel portions and the margin portion, a lower electrode provided on the organic insulating layer in the panel portions, an organic layer provided on the lower electrode and including a light emitting layer, and an upper electrode provided on the organic layer. In the margin portion including cut lines of the panel portions, the organic insulating layer comprises a removed portion, and comprises a stepwise cross section in which a thickness decreases toward the removed portion.

According to yet another embodiment, a manufacturing method of a display device comprises forming a lower electrode on an organic insulating layer in a display area which displays an image above a substrate, forming an organic layer including a light emitting layer on the lower electrode, and forming an upper electrode on the organic layer. The organic insulating layer is formed so as to form a removed portion and comprise a stepwise cross section in which a thickness decreases toward the removed portion in a surrounding area on an external side relative to the display area.

The embodiments can provide a display device, a mother substrate for a display device and a manufacturing method of a display device such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

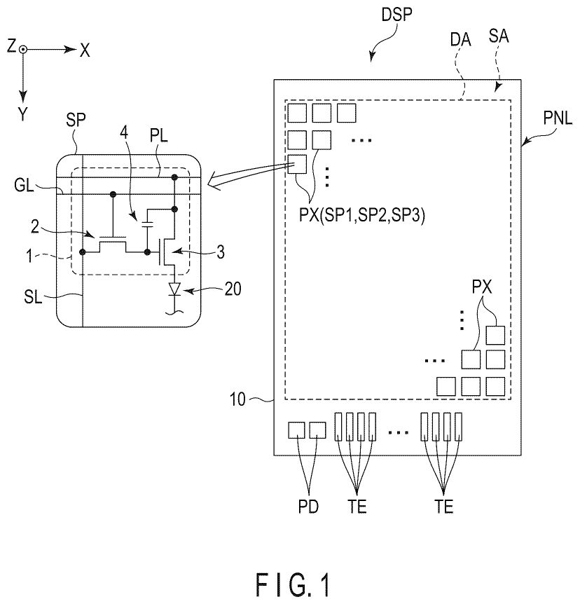

FIG. 1 is a diagram showing a configuration example of a display device DSP.

The display device DSP comprises a display panel PNL comprising a display area DA which displays an image and a surrounding area SA located on an external side relative to the display area DA on an insulating substrate 10. The substrate 10 may be glass or a resinous film having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

The surrounding area SA comprises a plurality of terminals TE for connecting an IC chip and a flexible printed circuit. The terminals TE are arranged in a single direction. In the example shown in the figure, the terminals TE are arranged in the first direction X. In the example shown in the figure, the surrounding area SA comprises pads PD used for inspection, etc. It should be noted that the pads PD may be omitted.

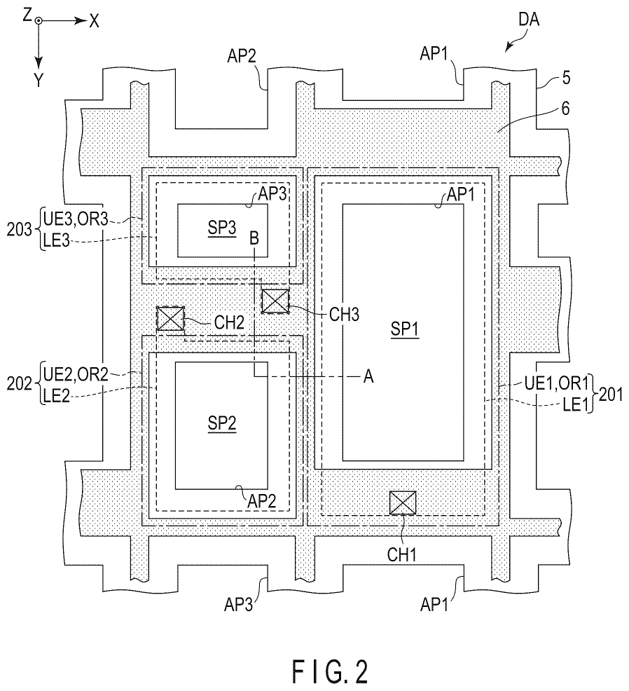

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 comprises apertures AP1, AP2 and AP3 in subpixels SP1, SP2 and SP3, respectively. The inorganic insulating layer 5 comprising these apertures AP1, AP2 and AP3 may be called a rib.

The partition 6 overlaps the inorganic insulating layer 5 in plan view. The partition 6 is formed into a grating shape surrounding the apertures AP1, AP2 and AP3. In other words, the partition 6 comprises apertures in subpixels SP1, SP2 and SP3 in a manner similar to that of the inorganic insulating layer 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The display element 201 comprising the lower electrode LE1, the organic layer OR1 and the upper electrode UE1 is surrounded by the partition 6 in plan view. The peripheral portion of each of the organic layer OR1 and the upper electrode UE1 overlaps the inorganic insulating layer 5 in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The display element 202 comprising the lower electrode LE2, the organic layer OR2 and the upper electrode UE2 is surrounded by the partition 6 in plan view. The peripheral portion of each of the organic layer OR2 and the upper electrode UE2 overlaps the inorganic insulating layer 5 in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The display element 203 comprising the lower electrode LE3, the organic layer OR3 and the upper electrode UE3 is surrounded by the partition 6 in plan view. The peripheral portion of each of the organic layer OR3 and the upper electrode UE3 overlaps the inorganic insulating layer 5 5 in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

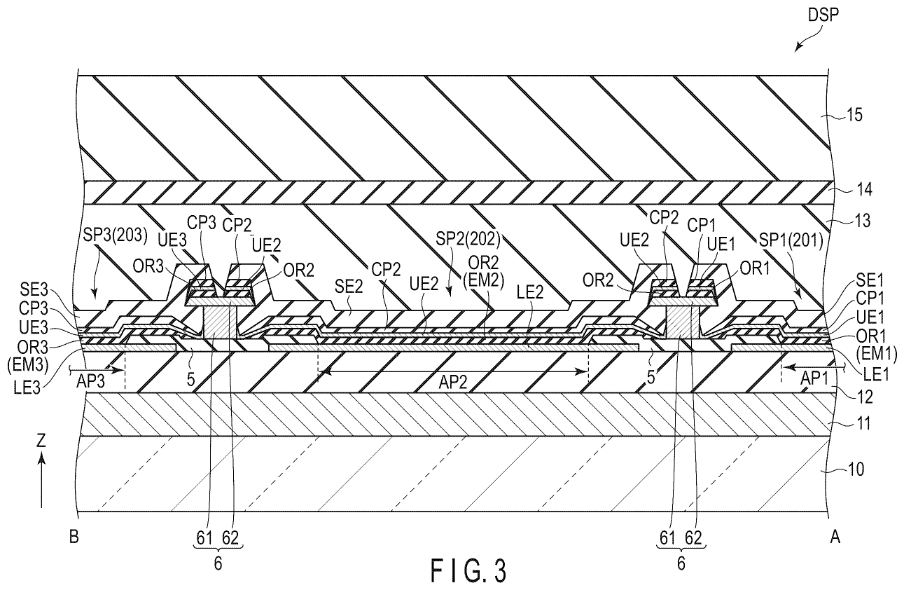

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The insulating layer 12 is covered with the inorganic insulating layer 5 between, of the lower electrodes LE1, LE2 and LE3, the lower electrodes which are adjacent to each other. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and CH3 of FIG. 2.

The partition 6 includes a conductive lower portion (stem) 61 provided on the inorganic insulating layer 5 and an upper portion (shade) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, insulating layer 12 and inorganic insulating layer 5 shown in FIG. 3 are provided over the display area DA and the surrounding area SA.

Now, this specification explains a mother substrate 100 for a display device (hereinafter, simply referred to as a mother substrate 100) for manufacturing a plurality of display devices DSP in a lump.

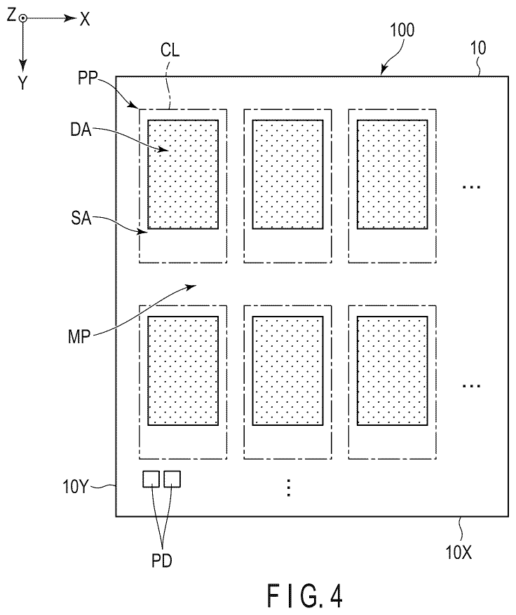

FIG. 4 is a plan view showing an example of the mother substrate 100.

The mother substrate 100 comprises a plurality of panel portions PP and a margin portion MP provided on an external side relative to these panel portions PP on a large substrate 10. The large substrate 10 is formed into a rectangular shape and comprises a linear first side 10X and a linear second side 10Y. The first side 10X extends in the first direction X. The second side 10Y extends in the second direction Y.

The panel portions PP are arrayed in matrix in the first direction X and the second direction Y. The panel portions PP are extracted by dividing the mother substrate 100 along cut lines CL. Each of the extracted panel portions PP corresponds to the display panel PNL shown in FIG. 1. Each cut line CL shown by one-dot chain lines in FIG. 4 corresponds to the outer shape of the display panel PNL. Each of the panel portions PP comprises a display area DA and a surrounding area SA.

The margin portion MP comprises, for example, a plurality of pads PD electrically connected to a test element group, etc.

FIG. 5 is a cross-sectional view showing a configuration example of the mother substrate 100 including a pad PD.

The pad PD shown in the figure corresponds to each pad PD of the surrounding area SA shown in FIG. 1 or each pad PD of the margin portion MP shown in FIG. 4. In FIG. 5, the illustration of the substrate 10 is omitted.

An insulating layer 111 is an inorganic insulating layer. A wiring layer 112 is provided on the insulating layer 111. An insulating layer 113 is an inorganic insulating layer and is provided on the wiring layer 112. The insulating layer 113 comprises an aperture OP113 from which the wiring layer 112 is exposed.

An insulating layer 114 is an organic insulating layer and is provided on the insulating layer 113. The insulating layer 114 comprises an aperture OP114 which overlaps the aperture OP113. In the example shown in the figure, the area of the aperture OP114 is greater than that of the aperture OP113. Thus, in addition to the wiring layer 112, part of the insulating layer 113 is exposed from the aperture OP114.

A metal layer MT is provided on the insulating layer 114, is provided on the insulating layer 113 in the aperture OP114, and is in contact with the wiring layer 112 in the aperture OP113. By this configuration, the metal layer MT is electrically connected to the wiring layer 112.

The insulating layer 12 is an organic insulating layer as described above, and is provided on the insulating layer 114 and the metal layer MT. The insulating layer 12 comprises an aperture OP12 from which the metal layer MT is exposed. The area of the aperture OP12 is less than that of the aperture OP113 and less than that of the aperture OP114.

The inorganic insulating layer 5 covers the insulating layer 12 and is in contact with the metal layer MT. The inorganic insulating layer 5 comprises an aperture OP5 which overlaps the aperture OP12. The metal layer MT is exposed from the aperture OP5. In the example shown in the figure, the area of the aperture OP5 is less than that of the aperture OP12.

In this configuration example, the insulating layer 114 corresponds to the first layer of the organic insulating layer, and the insulating layer 12 corresponds to the second layer located on the first layer in the organic insulating layer. The aperture OP12 of the insulating layer 12 corresponds to the removed portion LP of the organic insulating layer. When this specification focuses attention on the cross sectional shape of the organic insulating layer comprising these insulating layer 114 and insulating layer 12, the organic insulating layer comprises a stepwise cross section in which the thickness decreases toward the removed portion LP.

The insulating layer 114 has thickness T114. Thickness T114 corresponds to the length from the flat upper surface 113A of the insulating layer 113 to substantially the flat upper surface 114A of the insulating layer 114 in a third direction Z.

The insulating layer 12 has thickness T121 immediately above the insulating layer 114. The insulating layer 12 extends between the insulating layer 114 and the removed portion LP and has thickness T122 immediately above the metal layer MT.

Thickness T121 corresponds to the length from the upper surface 114A to substantially a flat upper surface 121A of the insulating layer 12 in the third direction Z. Thickness T122 corresponds to the length from substantially the flat upper surface MTA of the metal layer MT to substantially a flat upper surface 122A of the insulating layer 12 in the third direction Z.

Thickness T121 is greater than thickness T114. Thickness T122 is less than thickness T121 and less than thickness T114. The upper surface 122A is located on the lower side relative to the upper surface 121A and is located on the lower side relative to the upper surface 114A.

The organic insulating layer comprising this stepwise cross section can be formed by, for example, the following method.

First, the insulating layer 113 comprising the aperture OP113 is formed on the wiring layer 112. Subsequently, the insulating layer 114 comprising the aperture OP114 is formed. Subsequently, the metal layer MT which is in contact with the wiring layer 112 is formed. Subsequently, the insulating layer 12 comprising the aperture OP12 (removed portion LP) and having thickness T121 and thickness T122 is formed. This insulating layer 12 can be formed by, for example, the following method.

Specifically, for example, an insulating layer is formed by a positive organic material on the whole surface of the mother substrate 100 in which the metal layer MT is formed. Subsequently, the insulating layer is exposed to light. In this exposure process, the amount of exposure of the removed portion LP is set so as to be the maximum value, and the amount of exposure is set so as to decrease in stages from the removed portion LP toward the external side. Subsequently, the exposed insulating layer is developed. Subsequently, the insulating layer is baked.

By this process, the organic insulating layer comprising the cross sectional shape described above is formed.

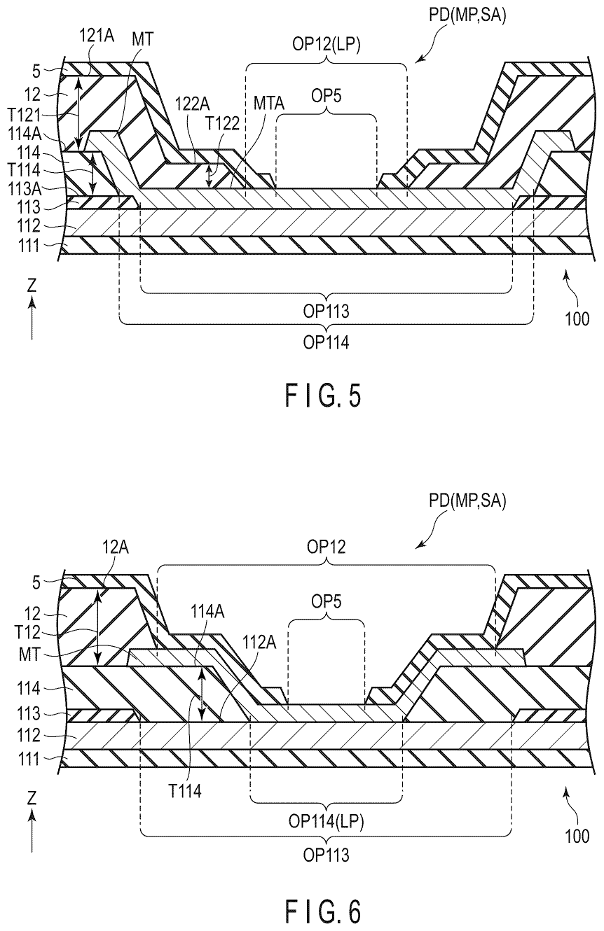

FIG. 6 is a cross-sectional view showing another configuration example of the mother substrate 100 including a pad PD.

The configuration example shown in FIG. 6 is different from that shown in FIG. 5 in the following respects. The insulating layer 114 extends between the insulating layer 12 and the removed portion LP. The aperture OP114 of the insulating layer 114 corresponds to the removed portion LP.

The insulating layer 114 is provided on the insulating layer 113 and is provided on the wiring layer 112 in the aperture OP113. The insulating layer 114 comprises the aperture OP114 (removed portion LP) from which the wiring layer 112 is exposed. The area of the aperture OP114 is less than that of the aperture OP113.

The metal layer MT is provided on the insulating layer 114 and is in contact with the wiring layer 112 in the aperture OP114. By this configuration, the metal layer MT is electrically connected to the wiring layer 112.

The insulating layer 12 is provided on the insulating layer 114 and the metal layer MT. The insulating layer 12 comprises the aperture OP12 from which the metal layer MT is exposed. The area of the aperture OP12 is greater than that of the aperture OP114. The insulating layer 12 is covered with the inorganic insulating layer 5.

The insulating layer 12 has thickness T12 immediately above the insulating layer 114. The insulating layer 114 extends between the insulating layer 12 and the aperture OP114 and has thickness T114 at a position overlapping the aperture OP113.

Thickness T114 corresponds to the length from substantially the flat upper surface 112A of the wiring layer 112 to substantially the flat upper surface 114A of the insulating layer 114 in the third direction Z. Thickness T12 corresponds to the length from the upper surface 114A to substantially the flat upper surface 12A of the insulating layer 12 in the third direction Z. Thickness T12 is greater than thickness T114. The upper surface 114A is located on the lower side relative to the upper surface 12A.

Thus, in this configuration example, similarly, the organic insulating layer comprising the insulating layer 114 and the insulating layer 12 comprises a stepwise cross section in which the thickness decreases toward the removed portion LP.

The organic insulating layer comprising this stepwise cross section can be formed by, for example, the following method.

First, the insulating layer 113 comprising the aperture OP113 is formed on the wiring layer 112. Subsequently, the insulating layer 114 comprising the aperture OP114 is formed. Subsequently, the metal layer MT which is in contact with the wiring layer 112 is formed. Subsequently, the insulating layer 12 comprising the aperture OP12 (removed portion LP) is formed. Subsequently, the inorganic insulating layer 5 comprising the aperture OP5 is formed.

By this process, the organic insulating layer comprising the cross sectional shape described above is formed.

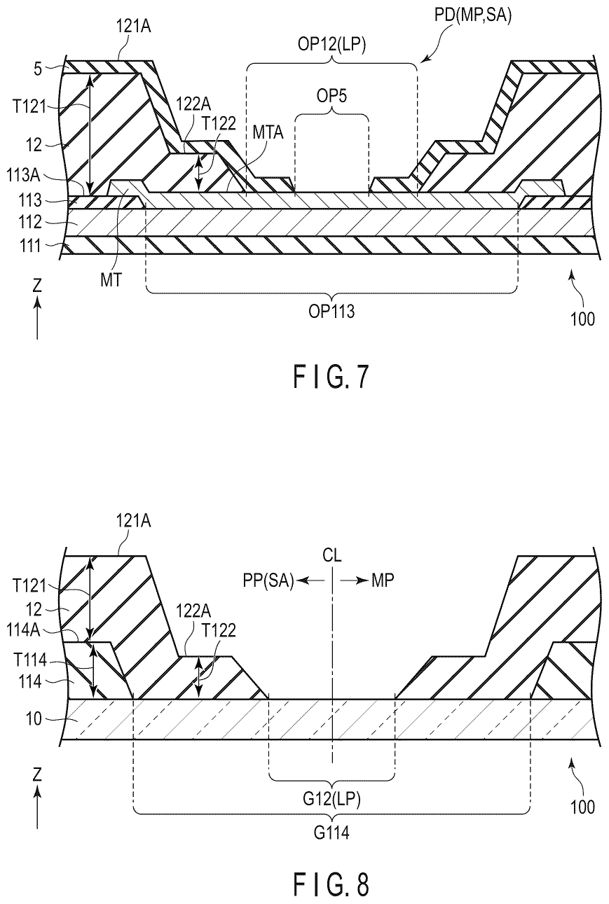

FIG. 7 is a cross-sectional view showing another configuration example of the mother substrate 100 including a pad PD.

The configuration example shown in FIG. 7 is different from that shown in FIG. 5 in the following respects. The organic insulating layer comprising a stepwise cross section is a single-layer body consisting of the insulating layer 12. The aperture OP12 of the insulating layer 12 corresponds to the removed portion LP. It should be noted that the insulating layer 114 shown in FIG. 5 is not present.

The insulating layer 12 is provided on the insulating layer 113 and the metal layer MT. The insulating layer 12 comprises the aperture OP12 (removed portion LP) from which the metal layer MT is exposed. The insulating layer 12 has thickness T121 immediately above the insulating layer 113 and has thickness T122 immediately above the metal layer MT. Thickness T121 corresponds to the length from the upper surface 113A of the insulating layer 113 to substantially the flat upper surface 121A of the insulating layer 12 in the third direction Z. Thickness T122 corresponds to the length from the flat upper surface MTA of the metal layer MT to substantially the flat upper surface 122A of the insulating layer 12 in the third direction Z. Thickness T121 is greater than thickness T122. The upper surface 122A is located on the lower side relative to the upper surface 121A.

The organic insulating layer comprising this stepwise cross section can be formed by, for example, the following method.

First, the insulating layer 113 comprising the aperture OP113 is formed on the wiring layer 112. Subsequently, the metal layer MT which is in contact with the wiring layer 112 is formed. Subsequently, the insulating layer 12 comprising the aperture OP12 (removed portion LP) and having thickness T121 and thickness T122 is formed. The formation method of the insulating layer 12 is as explained with reference to FIG. 5. Subsequently, the inorganic insulating layer 5 comprising the aperture OP5 is formed.

By this process, the organic insulating layer comprising the cross sectional shape described above is formed.

FIG. 8 is a cross-sectional view showing a configuration example of the mother substrate 100 including a cut line CL.

The left side of the cut line CL shown in the figure corresponds to the surrounding area SA of the panel portion PP. The right side of the cut line CL corresponds to the margin portion MP.

The insulating layer 114 is an organic insulating layer and is provided on the substrate 10. The insulating layer 114 comprises a groove G114 along the cut lie CL. The groove G114 is an area which penetrates the insulating layer 114. The substrate 10 is exposed from the groove G114. Another insulating layer may be interposed between the substrate 10 and the insulating layer 114.

The insulating layer 12 is an organic insulating layer and is provided on the insulating layer 114 and the substrate 10. The insulating layer 12 comprises a groove G12 along the cut line CL. The groove G12 is an area which penetrates the insulating layer 12. The substrate 10 is exposed from the groove G12. The width of the groove G12 is less than that of the groove G114.

In this configuration example, the insulating layer 114 corresponds to the first layer of the organic insulating layer, and the insulating layer 12 corresponds to the second layer located on the first layer in the organic insulating layer. The groove G12 of the insulating layer 12 corresponds to the removed portion LP of the organic insulating layer. When this specification focuses attention on the cross sectional shape of the organic insulating layer comprising these insulating layer 114 and insulating layer 12, the organic insulating layer comprises a stepwise cross section in which the thickness decreases toward the removed portion LP.

The insulating layer 114 has thickness T114. Thickness T114 corresponds to the length from the substrate 10 to substantially the flat upper surface 114A of the insulating layer 114 in the third direction Z.

The insulating layer 12 has thickness T121 immediately above the insulating layer 114. The insulating layer 12 extends between the insulating layer 114 and the removed portion LP and has thickness T122 immediately above the substrate 10. Thickness T121 corresponds to the length from the upper surface 114A to substantially the flat upper surface 121A of the insulating layer 12 in the third direction Z. Thickness T122 corresponds to the length from the substrate 10 to substantially the flat upper surface 122A of the insulating layer 12 in the third direction Z.

Thickness T121 is greater than thickness T114. Thickness T122 is less than thickness T121 and less than thickness T114. The upper surface 122A is located on the lower side relative to the upper surface 121A and is located on the lower side relative to the upper surface 114A.

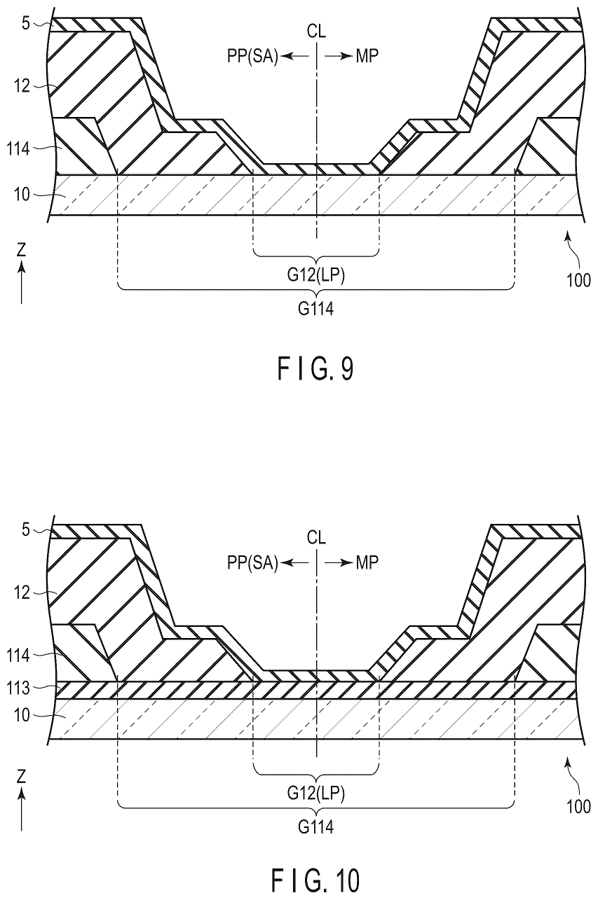

FIG. 9 is a cross-sectional view showing another configuration example of the mother substrate 100 including a cut line CL.

The configuration example shown in FIG. 9 is different from that shown in FIG. 8 in respect that the inorganic insulating layer 5 which covers the insulating layer 12 is added. The inorganic insulating layer 5 covers the substrate 10 in the groove G12 (removed portion LP).

FIG. 10 is a cross-sectional view showing another configuration example of the mother substrate 100 including a cut line CL.

The configuration example shown in FIG. 10 is different from that shown in FIG. 9 in respect that the insulating layer 113 which is the ground of the insulating layer 114 and the insulating layer 12 is added. The insulating layer 113 covers the substrate 10. In the groove G12 (removed portion LP), the insulating layer 113 and the inorganic insulating layer 5 are in contact with each other.

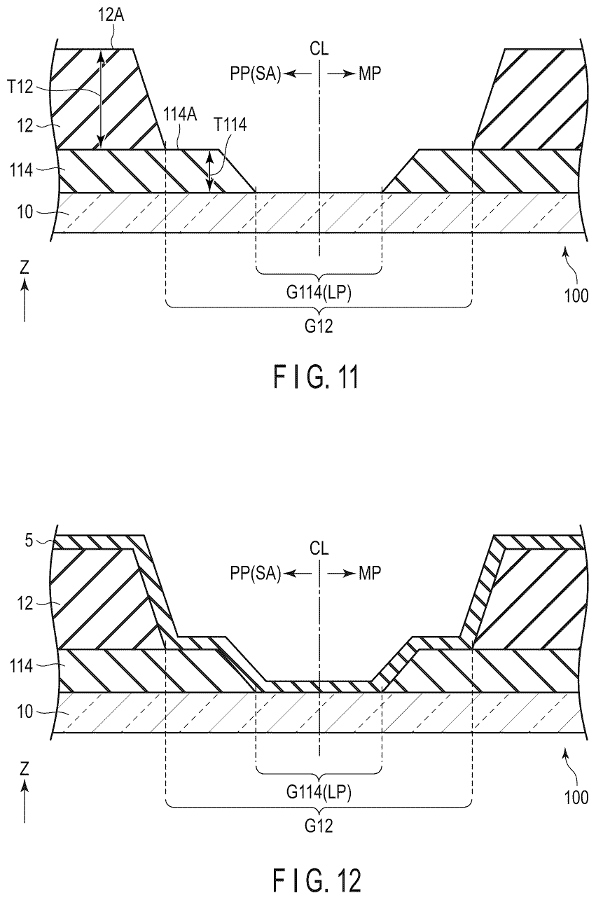

FIG. 11 is a cross-sectional view showing another configuration example of the mother substrate 100 including a cut line CL.

The insulating layer 114 is provided on the substrate 10 and comprises the groove G114 along the cut line CL. The insulating layer 12 is provided on the insulating layer 114 and comprises the groove G12 along the cut line CL. The width of the groove G12 is greater than that of the groove G114. In addition to the substrate 10, part of the insulating layer 114 is exposed from the groove G12.

In this configuration example, the insulating layer 114 corresponds to the first layer of the organic insulating layer, and the insulating layer 12 corresponds to the second layer located on the first layer in the organic insulating layer. The groove G114 of the insulating layer 114 corresponds to the removed portion LP of the organic insulating layer. When this specification focuses attention on the cross sectional shape of the organic insulating layer comprising these insulating layer 114 and insulating layer 12, the organic insulating layer comprises a stepwise cross section in which the thickness decreases toward the removed portion LP.

The insulating layer 12 has thickness T12 immediately above the insulating layer 114. The insulating layer 114 extends between the insulating layer 12 and the removed portion LP and has thickness T114 immediately above the substrate 10. Thickness T12 is greater than thickness T114. The upper surface 114A is located on the lower side relative to the upper surface 12A.

FIG. 12 is a cross-sectional view showing another configuration example of the mother substrate 100 including a cut line CL.

The configuration example shown in FIG. 12 is different from that shown in FIG. 11 in respect that the inorganic insulating layer 5 which covers the insulating layer 12 and the insulating layer 114 is added. The inorganic insulating layer 5 covers the substrate 10 in the groove G114 (removed portion LP).

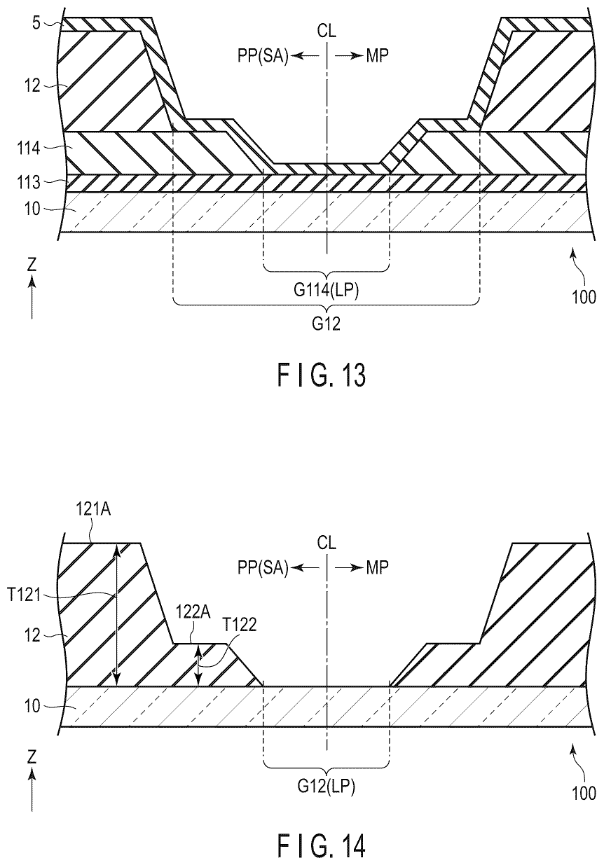

FIG. 13 is a cross-sectional view showing another configuration example of the mother substrate 100 including a cut line CL.

The configuration example shown in FIG. 13 is different from that shown in FIG. 12 in respect that the insulating layer 113 which is the ground of the insulating layer 114 is added. The insulating layer 113 covers the substrate 10. In the groove G114 (removed portion LP), the insulating layer 113 and the inorganic insulating layer 5 are in contact with each other.

FIG. 14 is a cross-sectional view showing another configuration example of the mother substrate 100 including a cut line CL.

The insulating layer 12 is provided on the substrate 10 and comprises the groove G12 along the cut line CL. The substrate 10 is exposed from the groove G12.

In this configuration example, the organic insulating layer comprising a stepwise cross section is a single-layer body consisting of the insulating layer 12. The groove G12 of the insulating layer 12 corresponds to the removed portion LP. The insulating layer 114 shown in FIG. 13, etc., is not present between the substrate 10 and the insulating layer 12.

The insulating layer 12 has thickness T121 and thickness T122. Thickness T121 corresponds to the length from the substrate 10 to substantially the flat upper surface 121A of the insulating layer 12 in the third direction Z. Thickness T122 corresponds to the length from the substrate 10 to substantially the flat upper surface 122A of the insulating layer 12 in the third direction Z. Thickness T121 is greater than thickness T122. The upper surface 122A is located on the lower side relative to the upper surface 121A.

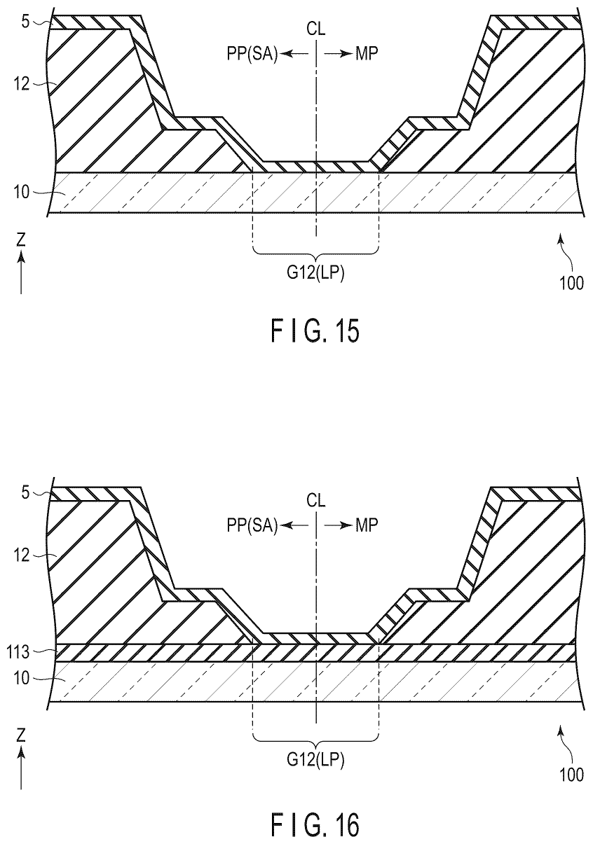

FIG. 15 is a cross-sectional view showing another configuration example of the mother substrate 100 including a cut line CL.

The configuration example shown in FIG. 15 is different from that shown in FIG. 14 in respect that the inorganic insulating layer 5 which covers the insulating layer 12 is added. The inorganic insulating layer 5 covers the substrate 10 in the groove G12 (removed portion LP).

FIG. 16 is a cross-sectional view showing another configuration example of the mother substrate 100 including a cut line CL.

The configuration example shown in FIG. 16 is different from that shown in FIG. 15 in respect that the insulating layer 113 which is the ground of the insulating layer 12 is added. The insulating layer 113 covers the substrate 10. In the groove G12 (removed portion LP), the insulating layer 113 and the inorganic insulating layer 5 are in contact with each other.

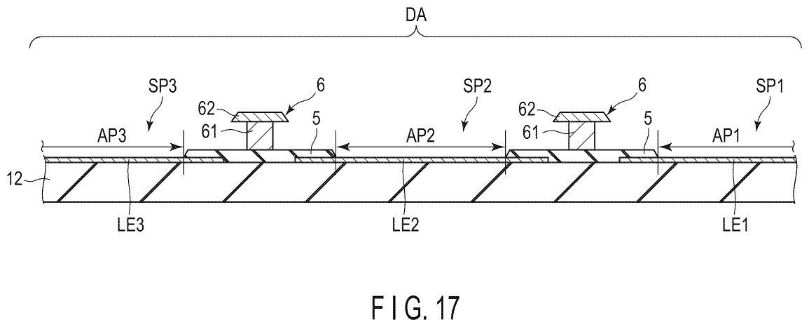

Now, this specification explains the manufacturing method of the display device DSP with reference to FIG. 17 to FIG. 22. In FIG. 17 to FIG. 22, the illustration lower than the insulating layer 12 is omitted.

First, as shown in FIG. 17, the lower electrode LE1 of subpixel SP1, the lower electrode LE2 of subpixel SP2 and the lower electrode LE3 of subpixel SP3 are formed on the insulating layer 12 in the display area DA. Subsequently, the inorganic insulating layer 5 is formed. The insulating layer 12 and the inorganic insulating layer 5 are formed in the surrounding area SA and the margin portion MP as well as the display area DA. The formation method of the insulating layer 12 in the surrounding area SA and the margin portion MP is, for example, as explained with reference to FIG. 5.

Subsequently, in the display area DA, the partition 6 which comprises the lower portion 61 located on the inorganic insulating layer 5 and the upper portion 62 located on the lower portion 61 is formed. Subsequently, the apertures AP1, AP2 and AP3 are formed in the inorganic insulating layer 5. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3. It should be noted that the formation process of the apertures AP1, AP2 and AP3 may be performed before the formation process of the partition 6.

Subsequently, the display element 201 is formed.

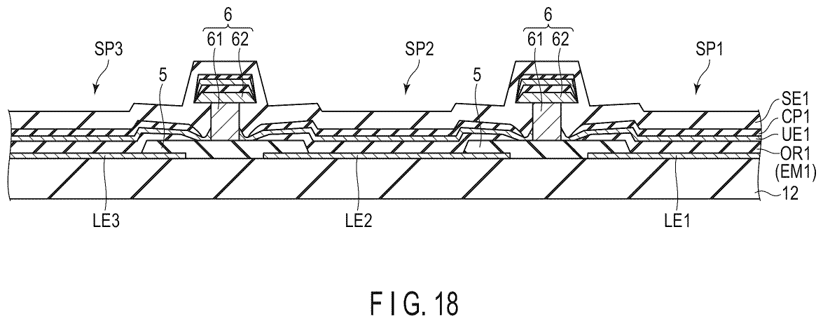

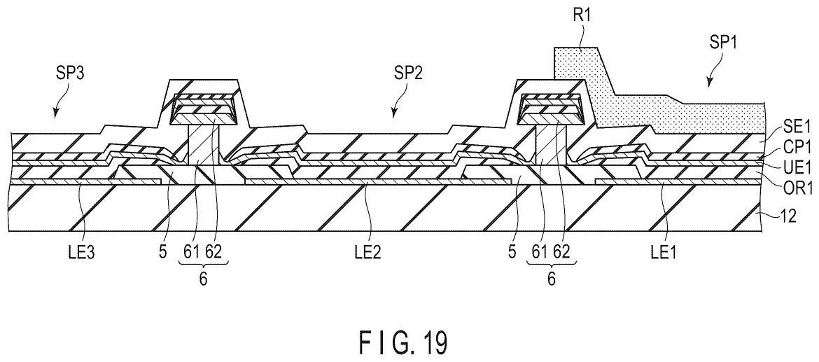

First, as shown in FIG. 18, the organic layer OR1 is formed by depositing the materials for forming the hole injection layer, the hole transport layer, the electron blocking layer, the light emitting layer EM1, the hole blocking layer, the electron transport layer, the electron injection layer, etc., on the lower electrode LE1 in series using the partition 6 as a mask.

Subsequently, the upper electrode UE1 is formed by depositing a mixture of magnesium and silver on the organic layer OR1 using the partition 6 as a mask. The upper electrode UE1 covers the organic layer OR1 and is in contact with the lower portion 61.

Subsequently, the cap layer CP1 is formed by depositing a high-refractive material and a low-refractive material in series on the upper electrode UE1 using the partition 6 as a mask.

These organic layer OR1, upper electrode UE1 and cap layer CP1 are successively formed while maintaining a vacuum environment.

Subsequently, the sealing layer SE1 is formed so as to continuously cover the cap layer CP1 and the partition 6.

The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

These organic layer OR1, upper electrode UE1, cap layer CP1 and sealing layer SE1 are formed in the surrounding area SA and the margin portion MP in addition to the display area DA.

Subsequently, as shown in FIG. 19, a resist R1 patterned into a predetermined shape is formed on the sealing layer SE1. The resist R1 overlaps subpixel SP1 and part of the partition 6 around subpixel SP1.

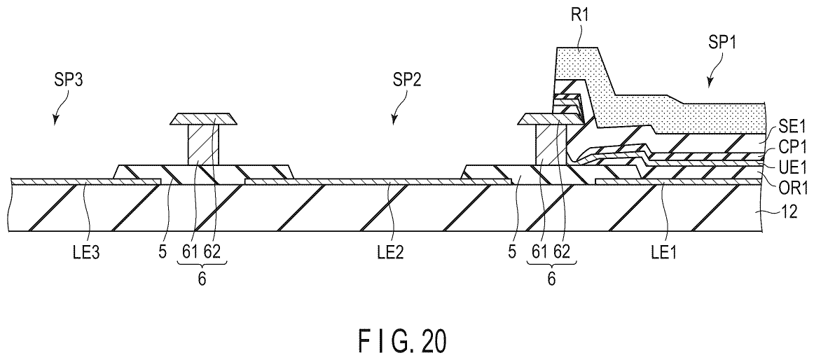

Subsequently, as shown in FIG. 20, the sealing layer SE1, cap layer CP1, upper electrode UE1 and organic layer OR1 exposed from the resist R1 are removed in series by performing etching using the resist R1 as a mask. In this manner, the lower electrode LE2 of subpixel SP2 and the lower electrode LE3 of subpixel SP3 are exposed.

Subsequently, the resist R1 is removed. By this process, the display element 201 is formed in subpixel SP1.

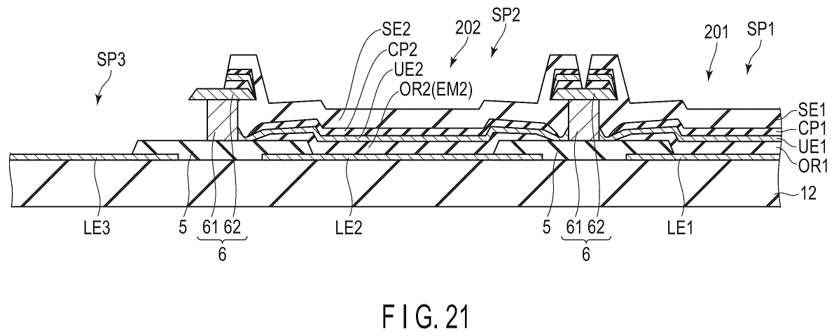

Subsequently, as shown in FIG. 21, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

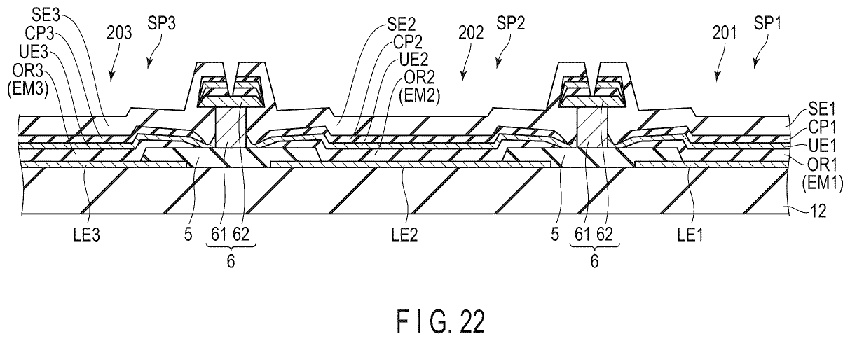

Subsequently, as shown in FIG. 22, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

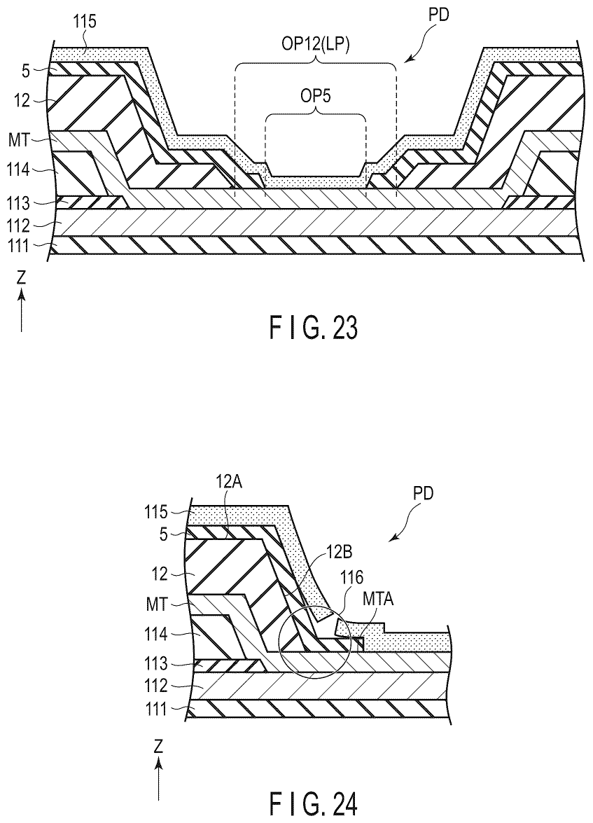

FIG. 23 is a cross-sectional view for explaining the state in which a multilayer film 115 is formed in the pad PD shown in FIG. 5.

In the process of forming each of the display elements 201, 202 and 203 described above, the multilayer film 115 is formed in the margin portion MP and the surrounding area SA as well. Here, the multilayer film 115 includes, for example, the organic layer OR1, the upper electrode UE1, the cap layer CP1 and the sealing layer SE1 for forming the display element 201 explained with reference to FIG. 18. The multilayer film 115 is formed on the inorganic insulating layer 5 and the metal layer MT.

In this configuration example, the organic insulating layer comprising the insulating layer 114 and the insulating layer 12 comprises a stepwise cross section in which the thickness decreases toward the removed portion LP. Thus, the formation of a steep step is prevented. Organic insulating layers have less elongation as the thickness decreases. Thus, when the multilayer film 115 is formed on the organic insulating layer, the distortion of the multilayer film 115 is less, and the local concentration of stress can be prevented in the multilayer film 115. In this manner, the removal of the multilayer film 115 from the pad PD can be prevented until the etching process explained with reference to FIG. 20.

Here, a case where the multilayer film 115 is formed in the pad PD is explained as an example of the removed portion LP of the organic insulating layer. However, similar effects can be obtained regarding a case where the multilayer film 115 is formed in a cut line CL as another example of the removed portion LP.

Even in a case where the multilayer film 115 includes the organic layer OR2, the upper electrode UE2, the cap layer CP2 and the sealing layer SE2 for forming the display element 202, similar effects are obtained.

Further, even in a case where the multilayer film 115 includes the organic layer OR3, the upper electrode UE3, the cap layer CP3 and the sealing layer SE3 for forming the display element 203, similar effects are obtained.

Now, a comparative example is explained.

FIG. 24 is a cross-sectional view for explaining the state in which a multilayer film 115 is formed in a pad PD according to a comparative example.

In the comparative example shown in FIG. 24, an insulating layer 12 comprises substantially a flat upper surface 12A, and an inclined surface 12B extending from the upper surface 12A to the upper surface MTA of a metal layer MT. The insulating layer 12 does not comprise the stepwise cross section of each configuration example described above.

According to the analysis of the inventor, in the comparative example shown in the figure, it was confirmed that stress was concentrated in a portion 116 in which the inorganic insulating layer 5, the insulating layer 12 and the metal layer MT were in contact with each other.

When the multilayer film 115 is formed in the pad PD of this comparative example, the multilayer film 115 is easily elevated from the inorganic insulating layer 5 and easily broken based on the portion 116 in which stress is concentrated. The multilayer film 115 removed from the inorganic insulating layer 5 floats inside the manufacturing device as foreign substances and could be a contaminant source. If the floating foreign substances are attached to the processing substrate, various defects could be caused.

As explained above, the embodiment can prevent the removal of the multilayer film 115 in the surrounding area SA and the margin portion MP. This configuration prevents the contamination of the manufacturing device and the generation of undesired foreign substances. In this manner, the reduction in reliability is prevented.

In the embodiment described above, for example, the inorganic insulating layer 5 corresponds to a first inorganic insulating layer. The insulating layer 113 corresponds to a second inorganic insulating layer. The insulating layer 114 corresponds to the first layer of an organic insulating layer. The insulating layer 12 corresponds to the second layer of the organic insulating layer.

As explained above, the embodiments can provide a display device, a mother substrate for a display device and a manufacturing method of a display device such that the reduction in reliability can be prevented.

All of the display devices, mother substrates and manufacturing methods that can be implemented by a person of ordinary skill in the art through arbitrary design changes to the display device, mother substrate and manufacturing method described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
an organic insulating layer provided over a display area which displays an image and a surrounding area located on an external side relative to the display area above the substrate;
a lower electrode provided on the organic insulating layer in the display area;
an organic layer provided on the lower electrode and including a light emitting layer; and
an upper electrode provided on the organic layer, wherein
in the surrounding area, the organic insulating layer comprises a removed portion and comprises a stepwise cross section in which a thickness decreases toward the removed portion.

2. The display device of claim 1, wherein
the organic insulating layer comprises a first layer and a second layer located on the first layer,
the second layer extends between the first layer and the removed portion, and
the removed portion is formed in the second layer.

3. The display device of claim 1, wherein
the organic insulating layer comprises a first layer and a second layer located on the first layer,
the first layer extends between the second layer and the removed portion, and
the removed portion is formed in the first layer.

4. The display device of claim 1, wherein
the organic insulating layer is a single-layer body.

5. The display device of claim 1, further comprising a first inorganic insulating layer which covers the organic insulating layer.

6. The display device of claim 5, further comprising a second inorganic insulating layer which is a ground of the organic insulating layer, wherein
the first inorganic insulating layer and the second inorganic insulating layer are in contact with each other in the removed portion.

7. The display device of claim 5, further comprising a metal layer exposed from the first inorganic insulating layer in the removed portion.

8. The display device of claim 5, wherein
the first organic insulating layer is provided in the display area and comprises an aperture overlapping the lower electrode.

9. The display device of claim 8, further comprising a partition comprising a lower portion provided on the first inorganic insulating layer and formed of a conductive material, and an upper portion provided on the lower portion and protruding from a side surface of the lower portion, wherein
the lower electrode, the organic layer and the upper electrode are surrounded by the partition, and
the upper electrode is in contact with the lower portion of the partition.

10. A mother substrate for a display device, comprising:
a plurality of panel portions;
a margin portion on an external side relative to the panel portions;
an organic insulating layer provided over the panel portions and the margin portion;
a lower electrode provided on the organic insulating layer in the panel portions;
an organic layer provided on the lower electrode and including a light emitting layer; and
an upper electrode provided on the organic layer, wherein
in the margin portion including cut lines of the panel portions, the organic insulating layer comprises a removed portion, and comprises a stepwise cross section in which a thickness decreases toward the removed portion.

11. The mother substrate of claim 10, further comprising a first inorganic insulating layer which covers the organic insulating layer and comprises an aperture overlapping the lower electrode.

12. The mother substrate of claim 11, further comprising a second inorganic insulating layer which is a ground of the organic insulating layer, wherein
the first inorganic insulating layer and the second inorganic insulating layer are in contact with each other in the removed portion.

13. The mother substrate of claim 11, further comprising a metal layer exposed from the first inorganic layer in the removed portion.

14. A manufacturing method of a display device, comprising:
forming a lower electrode on an organic insulating layer in a display area which displays an image above a substrate;
forming an organic layer including a light emitting layer on the lower electrode; and
forming an upper electrode on the organic layer, wherein
the organic insulating layer is formed so as to form a removed portion and comprise a stepwise cross section in which a thickness decreases toward the removed portion in a surrounding area on an external side relative to the display area.

15. The manufacturing method of claim 14, further comprising, after forming the lower electrode and before forming the organic layer,
forming a first inorganic insulating layer which covers the organic insulating layer and comprises an aperture overlapping the lower electrode.

16. The manufacturing method of claim 15, further comprising, after forming the first inorganic insulating layer and before forming the organic layer,
forming a partition comprising a conductive lower portion located on the first inorganic insulating layer and an upper portion located on the lower portion and protruding from a side surface of the lower portion, wherein
the organic layer and the upper electrode are formed by vapor deposition using the partition as a mask.

17. The manufacturing method of claim 16, further comprising, after forming the upper electrode,
forming a cap layer on the upper electrode by performing vapor deposition using the partition as a mask; and
forming a sealing layer which covers the partition and the cap layer.

18. The manufacturing method of claim 17, further comprising
forming a patterned resist on the sealing layer; and
removing part of the sealing layer, part of the cap layer, part of the upper electrode and part of the organic layer in series by performing etching using the resist as a mask.

19. The manufacturing method of claim 15, further comprising
forming a second inorganic insulating layer before forming the organic insulating layer, wherein
the first inorganic insulating layer and the second inorganic insulating layer are in contact with each other in the removed portion.

20. The manufacturing method of claim 15, further comprising
forming a metal layer exposed from the first inorganic insulating layer in the removed portion.
